(19) United States
(12) Patent Application Publication
(10) Pub. No.: US 2026/0040682 A1
(43) Pub. Date: Feb. 5, 2026

(54) CELL ARCHITECTURE INCLUDING SIGNAL LINE TRACKS ON FRONT SIDE AND BACK SIDE OF CELL

(71) Applicant: SAMSUNG ELECTRONICS CO., LTD., Suwon-si (KR)

(72) Inventors: Jinyoung LIM, Schenectady, NY (US); YoungGook PARK, Rensselaer, NY (US); Hyojong SHIN, Mechanicville, NY (US); Kang-ill SEO, Springfield, VA (US)

(73) Assignee: SAMSUNG ELECTRONICS CO., LTD., Suwon-si (KR)

(21) Appl. No.: 19/054,032

(22) Filed: Feb. 14, 2025

Related U.S. Application Data
(60) Provisional application No. 63/679,501, filed on Aug. 5, 2024.

(51) Int. Cl. H10D 84/90; H03K 19/20; H10D 89/10

(52) U.S. Cl. CPC H10D 84/981; H10D 84/953; H10D 84/975; H10D 89/10; H03K 19/20

(57) ABSTRACT

Provided is a cell architecture for a semiconductor device, which includes: at most thee frontside signal tracks provided at a same level on a front side of a semiconductor cell and extended in a 1^{st} direction in parallel with a 1^{st} boundary or a 2^{nd} boundary of the semiconductor cell, the 1^{st} boundary facing the 2^{nd} boundary in a 2^{nd} direction intersecting the 1^{st} direction; at least one backside signal track provided on a back side of the semiconductor cell and extended in the 1^{st} direction; and at least one signal line provided in at least one of the at most three frontside signal tracks and the at least one backside signal track and connected to at least one front-end-of-line (FEOL) structure or at least one middle-of-line (MOL) structure in the semiconductor cell, wherein the at most three frontside signal tracks are arranged in the 2^{nd} direction with a predetermined pitch, and wherein a sum number of the at most three frontside signal tracks and the at least one backside signal track is four.

### CROSS-REFERENCE TO RELATED APPLICATION

This application is based on and claims priority from U.S. Provisional Application No. 63/679,501 filed on Aug. 5, 2024 in the U.S. Patent and Trademark Office, the disclosure of which is incorporated herein in its entirety by reference.

### BACKGROUND

### 1. Filed

Apparatuses consistent with example embodiments of the disclosure relate to a cell architecture including a plurality of metal line tracks for a semiconductor device.

### 2. Description of Related Art

A semiconductor device for an integrated circuit may include a plurality of logic circuits (or logic gates) which perform one or more logic operations or functions such as AND, OR, NOT (inverter), NAND, NOR, XOR, XNOR, AOI, multiplexing, and their combination, not being limited thereto. These logic circuits are a building block of the integrated circuit, and may be implemented in one or more semiconductor cells. Hereafter, a semiconductor cell implementing a logic circuit may also be referred to as a cell, a function cell or a standard cell that can be stored in a cell library for designing and manufacturing a semiconductor device for an integrated circuit.

In designing a semiconductor cell, a latest trend includes scaling down a cell height, which refers to a length or width between an upper boundary and a lower boundary of the semiconductor cell which horizontally faces each other. Scaling down the cell height may be achieved by reducing the number of metal line tracks to be disposed inside the semiconductor cell in parallel with the upper boundary and the lower boundary thereof. The metal line tracks refer to placeholder structures where metal lines are to be disposed for power delivery or signal routing to and from active devices or passive devices to be formed in the semiconductor cell. Herein, a metal line track where a power rail is formed for power delivery is referred to as a power track, and a metal line track where a signal line is formed for signal routing is referred to as a signal track. The power rail and the signal line may each be a metal line formed of metal (e.g., copper (Cu), tungsten (W), aluminum (Al), ruthenium (Ru), molybdenum (Mo), titanium (Ti), tantalum (Ta), etc.) or a metal alloy thereof.

In the meantime, as a three-dimension (3D) stacked semiconductor device and a backside power delivery network (BSPDN) have been introduced to respond to an increased demand for high-density high-performance semiconductor devices, how to define an optimal number of metal line tracks in a semiconductor cell for the 3D-stacked semiconductor device has also been researched.

Here, the 3D-tacked semiconductor device may refer to a stacked field-effect transistor structure in which two field-effect transistors are respectively formed at a lower level and an upper level to achieve a high device density. Each of the two field-effect transistors may be a fin field-effect transistor (FinFET), a nanosheet transistor, a forksheet transistor or any other type of transistor. The FinFET has one or more vertical fin structures as a channel structure, in which at least three surfaces of each frontside signal track are surrounded by a gate structure, and the nanosheet transistor is characterized by one or more nanosheet channel layers vertically stacked on a substrate as a channel structure and a gate structure surrounding all four surfaces of each of the nanosheet channel layers. The nanosheet transistor is referred to as gate-all-around (GAA) transistor or as a multi-bridge channel field-effect transistor (MBCFET). The forksheet transistor may take a form of a combination of two nanosheet transistors with an isolation wall therebetween as an insulation backbone. Nanosheet channel layers of each nanosheet transistor in the forksheet transistor may be formed at each side of the isolation wall and pass through a gate structure of the nanosheet transistor at each side of the isolation wall.

The BSPDN for a semiconductor device has been introduced to address a heavy traffic of metal lines in the signal tracks and power tracks at a front side of the semiconductor device. The BSPDN is formed on a back side of a semiconductor device, and may include backside metal lines and backside source/drain contact structures respectively formed on bottom surfaces of source/drain regions of a field-effect transistor such as a nanosheet transistor, a FinFET, a forksheet transistor, etc. The backside metal lines may connect the backside contact structures to a voltage source or another circuit element for signal routing. The BSPDN may contribute to reducing contact resistance between circuit elements formed at the front side of the semiconductor device as well as reducing the size of the semiconductor device. Here, the front side refers to a side where a transistor structure including a channel structure, a gate structure, and source/drain regions is formed with respect to a top surface of a substrate, and the back side refers to a side opposite to the front side

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

Various example embodiments provide a cell layout of a cell architecture for a semiconductor cell of which a cell height may be reduced by decreasing the number of frontside signal tracks.

According to one or more embodiments, there is provided a cell architecture for a semiconductor device, which may include: at most thee frontside signal tracks provided at a same level on a front side of a semiconductor cell and extended in a 1^{st} direction in parallel with a 1^{st} boundary or a 2^{nd} boundary of the semiconductor cell, the 1^{st} boundary facing the 2^{nd} boundary in a 2^{nd} direction intersecting the 1^{st} direction; at least one backside signal track provided on a back side of the semiconductor cell and extended in the 1^{st} direction; and at least one signal line provided in at least one of the at most three frontside signal tracks and the at least one backside signal track and connected to at least one front-end-of-line (FEOL) structure or at least one middle-of-line (MOL) structure in the semiconductor cell, wherein the at most three frontside signal tracks are arranged in the 2^{nd} direction with a predetermined pitch, and wherein a sum number of the at most three frontside signal tracks and the at least one backside signal track is four.

According to one or more embodiments, there is provided a cell architecture for a semiconductor device, which may include: 1^{st} to 5^{th} frontside signal tracks extended in a 1^{st} direction and arranged in a 2^{nd} direction intersecting the 1^{st} direction on a front side of a semiconductor cell, and at least one signal line provided in at least one of the 2^{nd} to 4^{th} frontside signal tracks and connected to at least one front-end-of-line (FEOL) structure or at least one middle-of-line (MOL) structure in the semiconductor cell, wherein at least the 2^{nd} to 4^{th} frontside signal tracks are disposed at a same level in a 3^{rd} direction intersecting the 1^{st} direction and the 2^{nd} direction, wherein no other frontside signal track is disposed between the 1^{st} to 5^{th} frontside signal tracks, and wherein the 1^{st} frontside signal track overlaps a 1^{st} boundary of the semiconductor cell in a 3^{rd} direction intersecting the 1^{st} direction and the 2^{nd} direction, and the 5^{th} frontside signal track overlaps a 2^{nd} boundary of the semiconductor cell in the 3^{rd} direction, the 2^{nd} boundary facing the 1^{st} boundary in the 2^{nd} direction

According to one or more embodiments, there is provided a cell architecture for a semiconductor device, which may include: a plurality of transistors configured to perform a logic function within a semiconductor cell; three or less frontside signal tracks with a plurality of signal lines therein, the plurality of signal lines being connected to at least one of the plurality of transistors, wherein the frontside signal tracks are at a same level on a front side of the semiconductor cell inside a 1^{st} boundary and a 2^{nd} boundary of the semiconductor cell, and extended in a 1^{st} direction in parallel with the 1^{st} boundary or the 2^{nd} boundary, the 1^{st} boundary facing the 2^{nd} boundary in a 2^{nd} direction intersecting the 1^{st} direction; and one or more backside signal tracks with at least one backside signal line therein, the at least one signal line connecting at least two of the plurality of transistors.

### BRIEF DESCRIPTION OF DRAWINGS

Example embodiments of the disclosure will be more clearly understood from the following detailed description taken in conjunction with the accompanying drawings in which:

FIG. 1A illustrates a layout of a cell architecture for an exclusive NOR circuit with two inputs (XNOR2) implemented by a 3D-stacked semiconductor device in a top plan view, according to one or more embodiments;

FIG. 1B is a schematic of the XNOR2 circuit corresponding to the cell architecture shown in FIG. 1A, according to one or more embodiments;

FIG. 1C is a cross-section view of a portion of the cell architecture for the XNOR2 circuit shown in FIG. 1A along a line I-I′ thereof, according to one or more embodiments;

FIG. 2 illustrates a layout of a cell architecture for the XNOR2 circuit of FIG. 1, implemented by a 3D-stacked semiconductor device, according to one or more other embodiments;

FIG. 3A illustrates a layout of a cell architecture for the XNOR2 circuit of FIG. 1B implemented by a 3D-stacked semiconductor device;

FIG. 3B is a cross-section view of a portion of the cell architecture for the XNOR2 circuit shown in FIG. 2A along a line I-I′ thereof, according to one or more embodiments; and

FIG. 4 illustrates a layout of a cell architecture for a logic circuit implemented by a 3D-stacked semiconductor device including frontside signal tracks and backside signal tracks, according to one or more other embodiments; and

FIG. 5 is a schematic block diagram illustrating an electronic device including at least one semiconductor device formed based on at least one of the semiconductor cells 10-40 shown in FIGS. 1A-1C to 4, respectively, according to one or more embodiments.

### DETAILED DESCRIPTION

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements are differently oriented. Thus, herein, the “left” element and the “right” element may also be referred to as a “1^{st}” element and a “2^{nd}” element, respectively, or vice versa, as long as their structural relationship is clearly understood in the context of the descriptions. Similarly, the terms a “lower” element and an “upper” element may be respectively referred to as a “1^{st}” element and a “2^{nd}” element, or vice versa, with necessary descriptions to distinguish the two elements. Further, when a “1^{st}” element” of a structural element refers to one of a “left” element, a “right” element, a “top” element, a “bottom” element, etc. thereof while “a 1^{st}” element of another structural element may refer to another of these elements, with necessary descriptions to distinguish the two elements.

It will be understood that, although the terms “1^{st},” “2^{nd}” “3^{rd}” “4^{th},” “5^{th},” etc. may be used herein to describe various elements, these elements should not be limited by these terms. These terms are only used to distinguish one element from another element. Thus, a 1^{st} element discussed below could be termed a 2^{nd} element without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” is used to compare a dimension of two or more elements, the term may cover a “substantially same” dimension.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of a semiconductor device including a nanosheet transistor, a forksheet transistor or a FinFET, and materials forming the same may or may not be described in detail herein. For example, a certain isolation layer or structure of a semiconductor device and materials forming the same may be omitted herein when this layer or structure is not related to the novel features of the embodiments.

Herebelow, various embodiments of the disclosure directed to a cell architecture of a semiconductor cell in which an optimal number of signal tracks are formed on a front side and a back side of the semiconductor cell or a semiconductor device manufactured based on the semiconductor cell.

The inventors of the present application have identified that at least four frontside signal tracks to form metal lines (signal lines) therein are required for signal routing in a complex semiconductor cell to avoid an area penalty whether power rails are formed at a front side or a back side of a semiconductor device implemented by the semiconductor cell.

This requirement of at least four frontside signal tracks applies to a cell architecture in which all input pins and output pins for a logic circuit should be provided on a front side of a semiconductor cell. Further, requirement of at least four frontside signal tracks applies to a semiconductor cell designed to form a 3D-stacked semiconductor device including a BSPDN structure. Thus, the number of frontside signal tracks are considered an impediment in reducing a cell height of a semiconductor cell and a size of a semiconductor device to be formed based on the semiconductor cell.

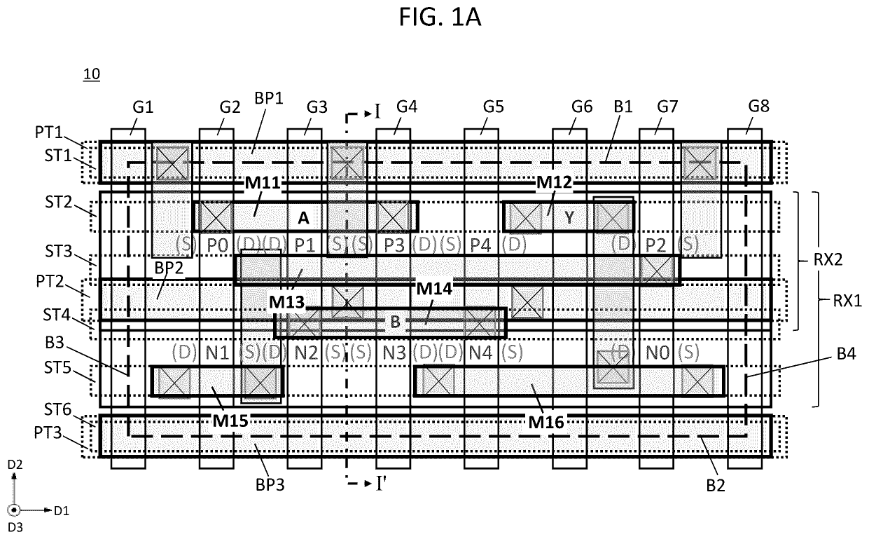

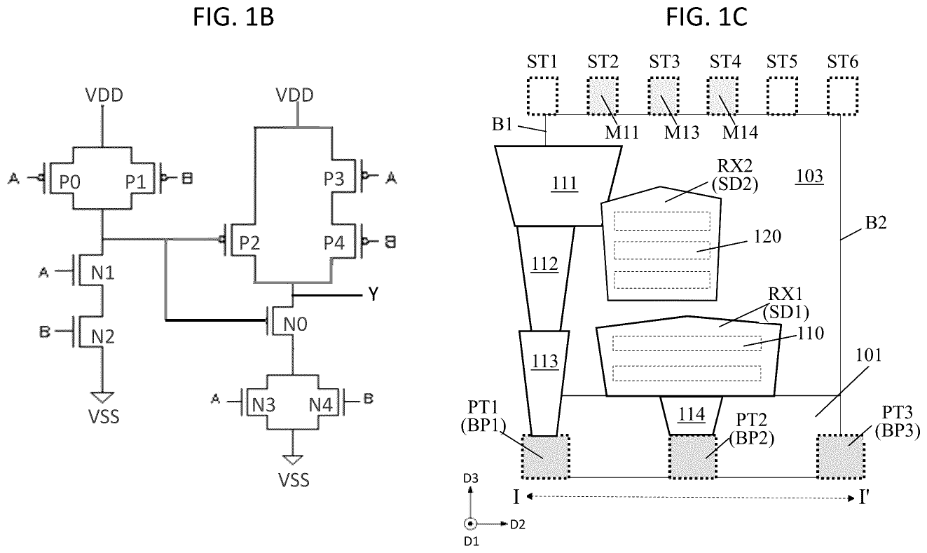

FIG. 1A illustrates a layout of a cell architecture for an exclusive NOR circuit with two inputs (XNOR2) implemented by a 3D-stacked semiconductor device in a top plan view, FIG. 1B is a schematic of the XNOR2 circuit corresponding to the cell architecture shown in FIG. 1A, and FIG. 1C is a cross-section view of a portion of the cell architecture for the XNOR2 circuit shown in FIG. 1A along a line I-I′ thereof, according to one or more embodiment.

Referring to FIGS. 1A-1C, a semiconductor cell 10 may be defined by a 1^{st} boundary B1, a 2^{nd} boundary B2, a 3^{rd} boundary B3, and a 4^{th} boundary B4. The 1^{st} boundary B1 and the 2^{nd} boundary B2 are extended in a 1^{st} direction D1 and face each other in a 2^{nd} direction D2 which intersects the 1^{st} direction D1. The 3^{rd} boundary B3 and the 4^{th} boundary B4 are extended in the 2^{nd} direction D2 and face each other in the 1^{st} direction D1.

In the semiconductor cell 10 may be formed a 1^{st} active region RX1 at a 1^{st} level and a 2^{nd} active region RX2 at a 2^{nd} level above the 1^{st} level in a 3^{rd} direction, which intersects the 1^{st} direction D1 and the 2^{nd} direction D2, and a plurality of gate structures (or gate lines) G1-G8 extended across the active regions RX1 and RX2 in the 2^{nd} direction D2 and arranged in the 1^{st} direction D1 with a predetermined contact-poly-pitch (CPP). Thus, the XNOR2 circuit formed in the semiconductor cell 10 may take a form of a 3D-stacked semiconductor device as shown in FIG. 1C. Among the eight gate structures, the 6^{th} gate structure G6, which may be a dummy gate structure, and the 1^{st} gate structure G1 on the 3^{rd} boundary B3 and the 8^{th} gate structure on the 4^{th} boundary B4 may not be used to form the XNOR2 circuit.

The 1^{st} active region RX1 may be provided to form channel structures and source/drain regions at the 1^{st} level of a 3D-stacked semiconductor device implemented in the semiconductor cell 10, and the 2^{nd} active region RX2 may be provided to form channel structures and source/drain regions at the 2^{nd} level of the 3D-stacked semiconductor device. For example, FIG. 1C shows that the 1^{st} active region RX1 forms a 1^{st} channel structure 110 including a plurality of nanosheet layers and a 1^{st} source/drain region SD1, and the 2^{nd} active region RX2 forms a 2^{nd} channel structure 120 including a plurality of nanosheet layers and a 2^{nd} source/drain region SD2. The 1^{st} source/drain region SD1 and the 2^{nd} source/drain region SD2 may be isolated from each other through an interlayer dielectric (ILD) structure 103.

Herein, the 1^{st} direction D1 refers to a channel length direction or active region length direction, the 2^{nd} direction is referred to as a channel width direction or active region width direction. The 1^{st} direction D1 and the 2^{nd} direction D2 both may be a horizontal direction, and the 3^{rd} direction D3 is a vertical direction. It is appreciated herein that the terms “semiconductor cell” and “semiconductor device” may be interchangeably used as the semiconductor device is to be manufactured to correspond to the semiconductor cell.

The 1^{st} active region RX1 may have a greater width than the 2^{nd} active region RX2 in the 2^{nd} direction D2 such that the 1^{st} active region RX1 is partially overlapped by the 2^{nd} active region RX2 in the 3^{rd} direction D3. This width difference may be provided to facilitate formation of an MOL structure (e.g., source/drain contact structure, via, etc.) on a top surface of a portion of the 1^{st} active region RX1 (e.g., a source/drain region) not overlapped by the 2^{nd} active region RX2 in the 3^{rd} direction D3.

The semiconductor cell 10 may also include 1^{st} to 3^{rd} backside power tracks PT1-PT3 on a back side thereof and 1^{st} to 6^{th} frontside signal tracks ST1-ST6 on a front side thereof. The backside power tracks PT1-PT3 and the frontside signal tracks ST1-ST6 may be extended in the 1^{st} direction D1 in parallel with the 1^{st} boundary B1 or the 2^{nd} boundary B2, and arranged in the 2^{nd} direction D2 with a predetermined pitch.

The 1^{st} backside power track PT1 and the 3^{rd} backside power track PT3 may be formed to overlap a 1^{st} boundary B1 and a 2^{nd} boundary B2 of the semiconductor cell 10, respectively, in the 3^{rd} direction D3, while the 2^{nd} backside power track PT2 may be formed inside the semiconductor cell 20 between the 1^{st} boundary B1 and the 2^{nd} boundary B2. Also, the 1^{st} frontside signal tracks ST1 and the 6^{th} frontside signal track ST6 may be referred to as boundary signal tracks which are formed to overlap the 1^{st} boundary B1 and the 2^{nd} boundary B2 of the semiconductor cell 10, respectively, in the 3^{rd} direction D3, while the 2^{nd} to 5^{th} frontside signal tracks ST2-ST5 may be formed inside the two boundaries B1 and B2 for signal routing for the 3D-stacked semiconductor device implemented by the semiconductor cell 10.

The 1^{st} backside power track PT1 and the 3^{rd} backside power track PT3 may be provided to form a 1^{st} backside power rail BP1 and a 3^{rd} backside power rail BP3 therein, respectively, which are connected to a positive voltage source VDD, and the 2^{nd} backside power track PT2 may be provided to form a 2^{nd} backside power rail BP2 therein which is connected to a negative voltage source VSS or ground. The backside power tracks PT1-PT3 with the backside power rails BP1-BP3 therein may be formed at a same level in the 3^{rd} direction D3 on the back side of the semiconductor cell 10,

The frontside signal tracks ST1-ST6 may be provided to form respective signal lines (metal lines) therein which connect at least some of a plurality of front-end-of-line (FEOL) structures such as source/drain regions and/or gate structures to each other or to an outside of the semiconductor cell 10. As the frontside signal tracks ST1-ST6 are arranged in the 2^{nd} direction D2 with the predetermined pitch, signal lines respectively formed therein may also be arranged in the 2^{nd} direction with the same predetermined pitch. Thus, distances between any two adjacent frontside signal tracks among the frontside signal tracks ST1-ST6 or signal lines therein may be the same.

As will be described below, the semiconductor cell 10 may use the 2^{nd} to 5^{th} frontside signal tracks ST2-ST5, that is, four signal tracks, to form 1^{st} to 6^{th} signal lines M11-M16 therein to constitute an XNOR2 circuit therein. The 1^{st} frontside signal track ST1 and the 6^{th} frontside signal track ST6 overlapping the two boundaries B1 and B2 in the 3^{rd} direction D3 and one or more signal lines to be formed therein may be shared between the semiconductor cell 10 and one or more adjacent semiconductor cells. However, as shown in FIG. 1C, the one or more signal lines formed in the 1^{st} frontside signal track ST1 or the 6^{th} frontside signal track ST6 may not be connected to an FEOL structure or an MOL structure in the semiconductor cell 10.

The frontside signal tracks ST1-ST6 with the signal lines M11-M16 therein may be formed at a same level, for example, M1 level, not being limited thereto, in the 3^{rd} direction D3 on the front side of the semiconductor cell 10. The frontside signal tracks ST1-ST6 may be the lowest frontside signal tracks in the semiconductor cell 10, and thus, no other frontside signal tracks may be formed below the frontside signal tracks ST1-ST6 above the active regions RX1 and RX2. The six signal lines M11-M16 may also be referred to as M1 metal lines at the M1 level or an M1 layer formed above the FEOL structures.

As shown in FIGS. 1A and 1i, an XNOR2 circuit may be formed by five (5) complementary metal-oxide-semiconductor (CMOS) devices. The five CMOS devices may include a 1^{st} CMOS device formed of a p-type metal-oxide-semiconductor transistor (PMOS) P0 and an n-type metal-oxide-semiconductor transistor (NMOS) N1, a 2^{nd} CMOS device formed of a PMOS P1 and an NMOS N2, a 3^{rd} CMOS device formed of a PMOS P3 and an NMOS N3, a 4^{th} CMOS device formed of a PMOS P4 and an NMOS N4, and a 5^{th} CMOS device formed of a PMOS P2 and an NMOS NO. Each of these CMOS devices is configured to receive a common gate input signal. For example, the 1^{st} CMOS device formed of the PMOS P0 and the NMOS N1 is configured to receive a common gate input signal as these two transistors share a same gate structure as will be described below in detail.

In the XNOR2 circuit shown in FIGS. 1A and 1B, the PMOSs P0, P1 and the NMOSs N1, N2 may form a NAND circuit, and the PMOSs P3, P4 and the NMOSs N3, N4 may form a NOR circuit. Further, the PMOS P2 and the NMOS NO may form a pass gate circuit.

The five CMOS devices may each may include a corresponding NMOS at the 1^{st} level and a corresponding PMOS at the 2^{nd} level above the 1^{st} level to form the XNOR2 circuit implemented by the semiconductor cell 10 as a 3D-stacked semiconductor device as shown in FIG. 1A. For example, to constitute the 1^{st} CMOS device, the PMOS P0 may be formed by the 2^{nd} gate structure G2, a portion of the 2^{nd} active region RX2 surrounded by (or below) the 2^{nd} gate structure G2 as a channel structure, and portions of the 2^{nd} active region RX2 at both sides of the 2^{nd} gate structure G2 as source/drain regions, and the NMOS N1 may be formed by the same 2^{nd} gate structure G2, a portion of the 1^{st} active region RX1 surrounded by (or below) the 2^{nd} gate structure G2 as a channel structure, and portions of the 1^{st} active region RX1 at both sides of the 2^{nd} gate structure G2 as source/drain regions. As another example, to constitute the 2^{nd} CMOS device, the PMOS P1 may be formed by the 3^{rd} gate structure G3, a portion of the 2^{nd} active region RX2 surrounded by (or below) the 3^{rd} gate structure G3 as a channel structure, and portions of the 2^{nd} active region RX2 at both sides of the 3^{rd} gate structure G3 as source/drain regions, and the NMOS N2 may be formed by the same 3^{rd} gate structure G3, a portion of the 1^{st} active region RX1 surrounded by (or below) the 3^{rd} gate structure G3 as a channel structure, and portions of the 1^{st} active region RX1 at both sides of the 3^{rd} gate structure G3 as source/drain regions.

The five CMOS devices formed of five PMOSs P0-P4 and five NMOSs NO-N4 in the semiconductor cell 10 may be powered by the backside power rails BP1-BP3 respectively formed in the backside power tracks PT1-PT3. For example, the backside power rail BP1 providing a positive voltage (VDD) may be connected to a source region (S) of the PMOS P0 on a left side of the gate structure G2 and a shared source region (S) of the PMOSs P1 and P3 between the gate structures G3 and G4 through a plurality of MOL structures 111, 112 and 113 (FIG. 1C). As another example, the backside power rail BP2 providing a negative or ground voltage (VSS) may be connected to a source region of the NMOS N4 on a right side of the gate structure G5 and a shared source region (S) of the NMOSs N2 and N3 between the gate structures G3 and G4 through a backside contact structure 114 (FIG. 1C). The backside power rails BP1 and BP2 may be connected to the respective source/drain regions of the foregoing transistors through corresponding contact structures such as the MOL structures 111, 112, 113 and the backside contact structure 114. The backside power tracks PT1-PT3 with the backside power rails BP1-BP3 and the backside contact structure 114 may be formed in a backside isolation structure 101 as shown in FIG. 1C.

It is understood here that, unlike frontside power rails of which positions are limited to the 1^{st} boundary B1 and the 2^{nd} boundary B2 in a related-art cell architecture, the backside power track PT2 with the backside power rail BP2 therein may be disposed inside the semiconductor cell 10 to reduce a connection distance, thereby decreasing contact resistance, and improve device density.

Herebelow, signal routing to function the XNOR2 circuit implemented in the semiconductor cell 10 is described.

The 1^{st} signal line M11 formed in the 2^{nd} frontside signal track ST2 may receive a 1^{st} gate input signal A from an outside of the semiconductor cell 10 and provide the 1^{st} gate input signal A commonly to the gate structure G2 of the PMOS P0 and the NMOS N1 and the gate structure G4 of the PMOS P3 and the NMOS N3 through at least one MOL structure. Similarly, the 4^{th} signal line M14 formed in the frontside signal track ST4 may receive a 2^{nd} gate input signal B from the outside of the semiconductor cell 10 and provide the 2^{nd} gate input signal B commonly to the gate structures G3 of the PMOS P1 and the NMOS N2 and the gate structure G5 of the PMOS P4 and the NMOS N4 through at least one MOL structure. Here, the 1^{st} signal line M11 and the 4^{th} signal line M14 may be referred to as input pints of the semiconductor cell 10.

The 5^{th} signal line M15 formed in the 5^{th} frontside signal track ST5 may connect a drain region (D) of the NMOS N1 on a left side the gate structure G2 to a shared drain region (D) of the PMOSs P0 and P1 between the gate structures G2 and G3 through at least one MOL structure, and the 3^{rd} signal line M13 formed in the frontside signal track ST3 may connect the shared drain region (D) of the PMOSs P0 and P1 to the gate structure G7 of the PMOS P2 and the NMOS NO which forms a pass gate circuit of the XNOR2 circuit through at least one MOL structure. Thus, an output signal of the NAND circuit of the XNOR2 circuit may be output from the drain regions (D) of the PMOSs P0, P1 and the NMOS N1 to be input to the NOR circuit of the XNOR circuit through the two pass gates, that is, the PMOS P2 and the NMOS NO.

The 6^{th} signal line M16 formed in the 5^{th} frontside signal track ST5 may connect a source region (S) of the NMOS NO on a right side of the gate structure G7 to a shared drain region (D) of the NMOS N3 and N4 between the gate structures G4 and G5 through at least one MOL structure.

The 2^{nd} signal line M12 formed in the 2^{nd} frontside signal track ST2 may connect a drain region (D) of the PMOS P4 on a right side of the gate structure G5 to a drain region (D) of the PMOS P2 on a left side of the gate structure G7 through at least one MOL structure. Further, the drain region (D) of the PMOS P2 on the left side of the gate structure G7 may be connected to a drain region (D) of the NMOS NO on a left side of the gate structure G7 through at least one MOL structure. Thus, an output signal of the XNOR2 circuit may be output from the drain regions (D) of the PMOSs P2, P4 and the NMOS NO. Here, the 2^{nd} signal line M12 may be referred to as an output pin of the semiconductor cell 10.

As described above, in order to implement a logic circuit such as the XNOR2 circuit of FIG. 1B by a semiconductor cell for a 3D-stacked semiconductor device in which all input pins and output pins are provided in a front side of the semiconductor cell, the semiconductor cell requires four frontside signal tracks extended in the 1^{st} direction D1 at the M1 level to form necessary M1 metal lines therein for signal routing, while the semiconductor cell is powered by backside power rails. Thus, there is a limit to reduce a cell height of the semiconductor cell for the 3D-stacked semiconductor device because of the minimum number, that is, four, of the frontside signal tracks for M1 metal lines.

To address this problem, one or more additional frontside signal tracks for upper-level metal lines may be formed while the number of the frontside signal tracks for the M1 metal lines is reduced as described below.

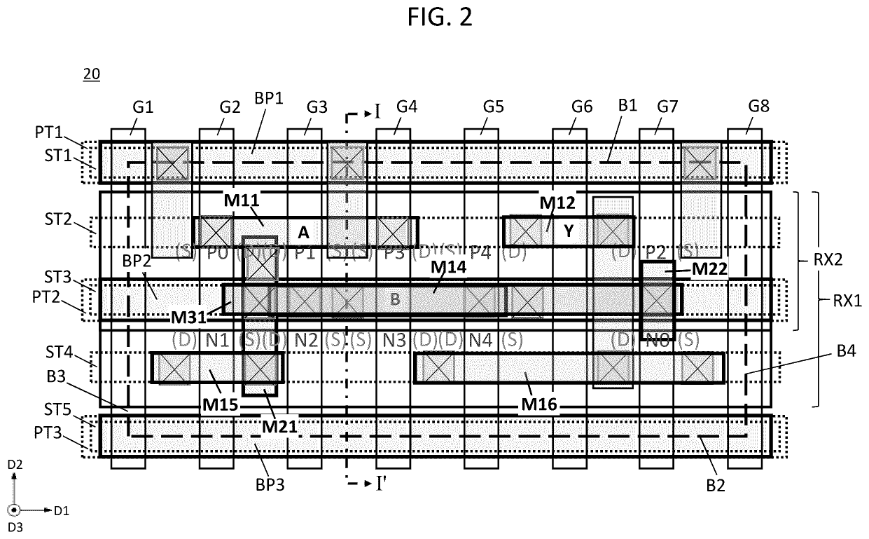

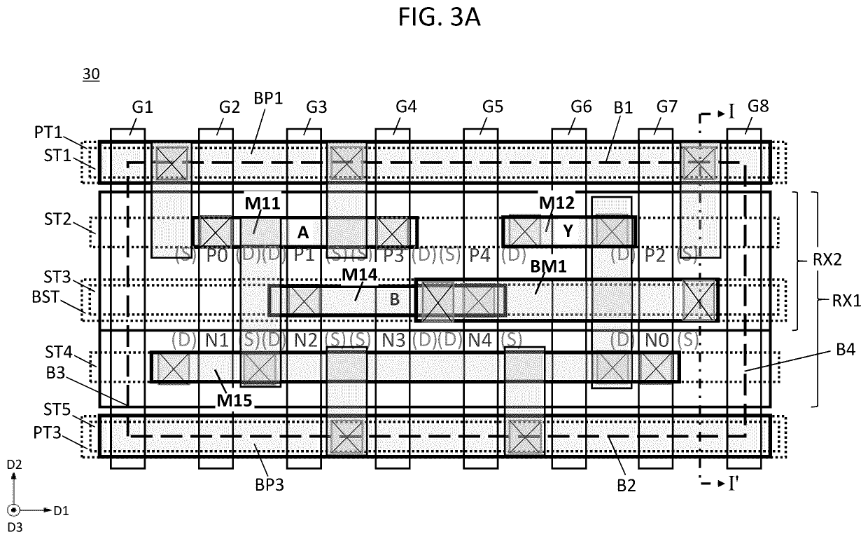

FIG. 2 illustrates a layout of a cell architecture for the XNOR2 circuit of FIG. 1, implemented by a 3D-stacked semiconductor device, according to one or more other embodiments.

Referring to FIG. 2, a semiconductor cell 20 may be formed to implement the same XNOR2 circuit implemented in the semiconductor cell 10 of FIG. 1A based on the same FEOL structures including the 1^{st} active region RX1, the 2^{nd} active region RX2 and the gate structures G1-G8, and the backside power rails BP1-BP3. Thus, duplicate descriptions thereof may be omitted herein. However, the semiconductor cell 20 differs from the semiconductor cell 10 in that the number of the frontside signal tracks at the M1 level disposed between the two boundaries B1 and B2 is reduced from four to three, and instead, upper-level metal lines and corresponding MOL structures are added.

For example, the semiconductor cell 20 may include only three frontside signal tracks ST2-ST4 between the two boundaries B1 and B2, and include two M2 signal lines M21 and M22 at an M2 level above the M1 level in the 3^{rd} direction D3 and an M3 signal line M31 at an M3 level above the M2 level in the 3^{rd} direction D3. The two M2 signal lines M21, M22 and the M3 signal line M31 may be formed in respective upper-level signal tracks above the frontside signal tracks ST1-ST5 on the front side of the semiconductor cell 20.

The M2 signal line M21 connects the 5^{th} signal line M15, connected to the drain region D of the NMOS N1 on the left side of the gate structure G2, to the shared drain region (D) of the PMOSs P0 and P1 between the gate structures G2 and G3 through at least one MOL structure. This M2 signal line M21 is connected to the M3 signal line M31 though an MOL structure, and the M3 signal line M31 is connected to the gate structure G7 of the PMOS P2 and the NMOS NO which forms the pass gate circuit of the XNOR2 circuit through another M2 signal line M22 and at least one MOL structure. Thus, in the semiconductor cell 20, the output signal of the NAND circuit of the XNOR2 circuit is delivered to the PMOS P2 and the NMOS N0, which are pass gates of the NOR circuit of the XNOR2 circuit through the 5^{th} signal line M15 in the 5^{th} frontside signal track ST4, an M2 signal line M21, and an M3 signal line M31, and another M2 signal line M22.

Further, the 5^{th} signal line M15 and the 6^{th} signal line M16, which are formed in the 5^{th} frontside signal track ST5 in the semiconductor cell 10, may now be formed in the 4^{th} frontside signal track ST4 in the semiconductor cell 20.

In the semiconductor cell 20, as the number of the frontside signal tracks is reduced from four to three compared to the semiconductor cell 20, a cell height of the semiconductor cell 20 may be reduced as much as a single pitch of the frontside signal tracks ST1-ST6 of the semiconductor cell 10. Thus, the frontside signal tracks ST1-ST5 in the semiconductor cell 20 may have the same predetermined pitch of the frontside signal tracks ST1-ST6 in the semiconductor cell 10. Also, in the semiconductor cell 20, the 1^{st} frontside signal track ST1 and the 5^{th} frontside signal track ST5 overlapping the two boundaries B1 and B2 in the 3^{rd} direction D3 and one or more signal lines to be formed therein may be shared between the semiconductor cell 20 and one or more adjacent semiconductor cells. However, as shown in FIG. 1B, the one or more signal lines formed in the 1^{st} frontside signal track ST1 or the 5^{th} frontside signal track ST5 may not be connected to an FEOL structure or an MOL structure in the semiconductor cell 20.

As described above, the semiconductor cell 20 may be able to reduce the number of the frontside signal tracks at the M1 level to decrease a cell height at the expense of adding upper-level signal tracks for signal routing. However, signal lines formed in the upper-level signal tracks may prevent or disrupt signal routing between semiconductor cells through a space above the semiconductor cell 20 in the 3^{rd} direction D3 because of the upper-level metal lines. Further, a size of the semiconductor cell 20 and a 3D-stacked semiconductor device formed based on the semiconductor cell 20 may become larger in the 3^{rd} direction because of these upper-metal lines.

Thus, the following embodiments provide a cell architecture for a semiconductor cell for a 3D-stacked semiconductor device in which the number of the frontside signal tracks is reduced without adding an upper-level metal lines for signal routing.

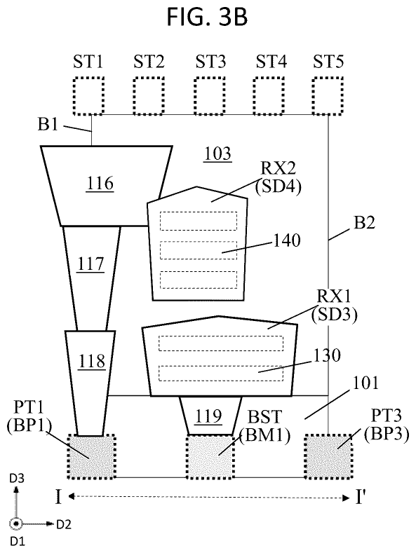

FIG. 3A illustrates a layout of a cell architecture for the XNOR2 circuit of FIG. 1B implemented by a 3D-stacked semiconductor device, and FIG. 3B is a cross-section view of a portion of the cell architecture for the XNOR2 circuit shown in FIG. 2A along a line I-I′ thereof, according to one or more embodiments.

Referring to FIG. 3A, a semiconductor cell 30 may be formed to implement the same XNOR2 circuit implemented in the semiconductor cell 20 of FIG. 2 based on the same FEOL structures including the 1^{st} active region RX1, the 2^{nd} active region RX2 and the gate structures G1-G8. Thus, duplicate descriptions thereof may be omitted herein. However, the semiconductor cell 30 differs from the semiconductor cell 20 in that, instead of adding the upper-level metal lines M21, M22 and M31, one of the existing backside power tracks is changed to a backside signal track on a back side of the semiconductor cell 30, and at least one frontside signal track includes a different signal line.

Like the semiconductor cell 20 of FIG. 2, the semiconductor cell 30 may also include only three frontside signal tracks ST2-ST4 between the two boundaries B1 and B2, and instead, the 2^{nd} backside power track PT2 in the semiconductor cell 20 (also in the semiconductor cell 10 of FIG. 1A) may be changed to or replaced by a backside signal track BST in the semiconductor cell 30 so that a backside signal line (metal line) BM1 is formed in the backside signal track BST. The backside signal line BM1 is a replacement of the 6^{th} signal line M16 in the semiconductor cell 20 (also in the semiconductor cell 10 of FIG. 1A) which connects the source region (S) of the NMOS N0 on the right side of the gate structure G7 to the shared drain region (D) of the NMOSs N3 and N4 between the gate structures G4 and G5.

In the semiconductor cells 10 and 20, the signal line M16 is formed in the 4^{th} frontside signal track ST4 or 5^{th} frontside signal track ST5 where the signal line M15 is formed. Thus, the signal line M15 should be connected to another signal line M13 in another frontside signal track ST3 (in the semiconductor cell 10) or the upper-level signal lines M21, M31 and M22 (in the semiconductor cell 20) to deliver an output signal of the NAND circuit of the XNOR2 circuit from the drain regions (D) of the PMOS P0, P1 and the NMOS N1 to the pass gate circuit, that is, the PMOS P2 and the NMOS N2, for the NOR circuit of the XNOR2 circuit. However, in the semiconductor cell 30, the backside signal track BST is formed to include the backside signal line BM1 therein to connect the source region (S) of the NMOS N0 on the right side of the gate structure G7 to the shared drain region (D) of the NMOSs N3 and N4 between the gate structures G4 and G5 through a backside contact structure 119 (shown in FIG. 3B). In FIG. 3B, the source/drain region SD3 may be the shared drain region (D) of the NMOSs N3 and N4.

Thus, the semiconductor cell 30 may achieve signal routing for the XNOR2 circuit using only three frontside signal tracks with corresponding signal lines formed therein and one backside signal track with a corresponding backside signal line, while the 1^{st} signal line M11 and the 4^{th} signal line M14 remain as input pins and the 2^{nd} signal line M12 remains as an output pin on the front side of the semiconductor cell 30 for a 3D-stacked semiconductor device.

In the meantime, in the semiconductor cells 10 and 20, the 2^{nd} backside power track PT2 is provided to form the 2^{nd} backside power rail BP2 connected to the negative voltage source VSS or ground to power the NMOSs N2-N4. However, as this 2^{nd} backside power track PT2 is changed to or replaced by the backside signal track BST, one of the 1^{st} backside power track PT1 and the 3^{rd} backside power track PT3 needs to form a backside power rail therein connected to the negative voltage source VSS or ground. For example, in semiconductor cell 30, the backside power rail BP3 in the 3^{rd} backside power track PT3 may be connected to the negative voltage source VSS or ground through at least one backside contact structure to power the NMOSs N2-N4. Still, the 1^{st} backside power track PT1 with the 1^{st} backside power rail BP1 may be connected to corresponding FEOL structures such as the source/drain region SD4 (FIG. 3B) which may be the source region (S) of the PMOS P2 though a plurality of MOL structures 116, 117 and 118 (FIG. 3B).

In the semiconductor cell 30, as the number of the frontside signal tracks is reduced from four to three compared to the semiconductor cell 10, a cell height of the semiconductor cell 30 may be reduced as much as a single pitch of the frontside signal tracks ST1-ST6 of the semiconductor cell 10. Thus, the frontside signal tracks ST1-ST5 in the semiconductor cell 30 may have the same predetermined pitch of the frontside signal tracks ST1-ST6 in the semiconductor cell 10. Also, in the semiconductor cell 30, the 1^{st} frontside signal track ST1 and the 5^{th} frontside signal track ST5 overlapping the two boundaries B1 and B2 in the 3^{rd} direction D3 and one or more signal lines to be formed therein may be shared between the semiconductor cell 20 and one or more adjacent semiconductor cells. However, as shown in FIG. 3B, the one or more signal lines formed in the 1^{st} frontside signal track ST1 or the 5^{th} frontside signal track ST5 may not be connected to an FEOL structure or an MOL structure in the semiconductor cell 30

In the above semiconductor cell 30, three frontside signal tracks ST2-ST4 and one backside signal track BST are formed between the two boundaries B1 and B2 to include respective signal lines therein to implement the XNOR2 circuit in a 3D-stacked semiconductor device. However, the disclosure is not limited thereto, and, according to one or more other embodiments, a different logic circuit may be implemented by the semiconductor cell 30 based on the same three frontside signal tracks ST2-ST4 and one backside signal track BST by changing the formation of the FEOL structures, the MOL structures, and the signal lines formed in the signal tracks. Further, the number of the frontside signal tracks may be reduced to two or one while the number of the backside signal tracks is increased to implement the same or different logic circuit formed in the semiconductor cell 30, according to one or more other embodiments as described below.

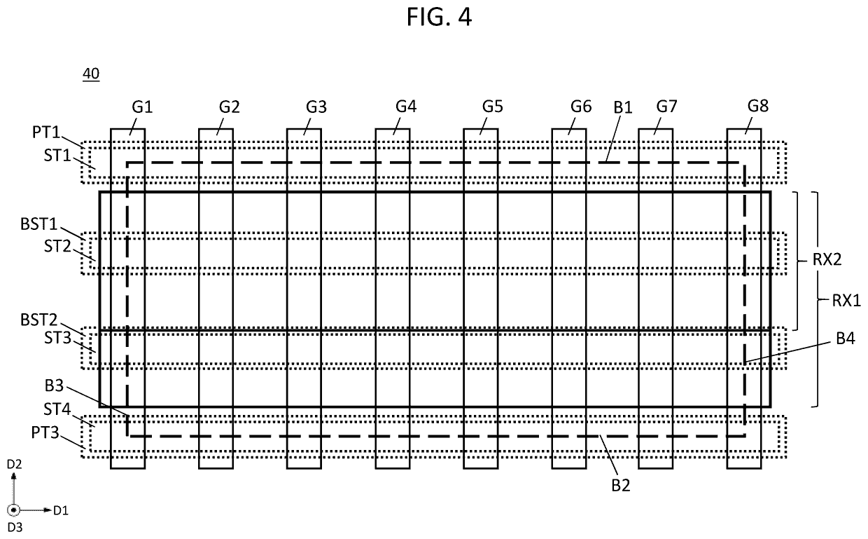

FIG. 4 illustrates a layout of a cell architecture for a logic circuit implemented by a 3D-stacked semiconductor device including frontside signal tracks and backside signal tracks, according to one or more other embodiments.

Referring to FIG. 4, a semiconductor cell 40 may be formed to include the same active regions RX1, RX2, gate structures G1-G8, and backside power tracks PT1 and PT3 as in the semiconductor cell 30 of FIG. 3A. However, the semiconductor cell 40 differs from the semiconductor cell 30 in that two frontside signal tracks ST2 and ST3 and two backside signal tracks BST1 and BST2 are formed between two boundaries B1 and B2 for signal routing for a logic circuit formed therein. Still, however, all input pins and output pins for the logic circuit such as the XNOR2 circuit, not being limited thereto, may be formed on a front side of the semiconductor cell 40, for example, one or more signal lines to be formed in the frontside signal tracks ST2 and ST3.

In the semiconductor cell 40, as the number of the frontside signal tracks is reduced from three to two compared to the semiconductor cell 30, a cell height of the semiconductor cell 40 may be reduced as much as a single pitch of the frontside signal tracks ST1-ST5 of the semiconductor cell 30. Thus, the frontside signal tracks ST1-ST4 in the semiconductor cell 40 may have the same predetermined pitch of the frontside signal tracks ST1-ST5 in the semiconductor cell 30.

Also, in the semiconductor cell 40, the 1^{st} frontside signal track ST1 and the 4^{th} frontside signal track ST4 overlapping the two boundaries B1 and B2 in the 3^{rd} direction D3 and one or more signal lines to be formed therein may be shared between the semiconductor cell 40 and one or more adjacent semiconductor cells. Further, in the semiconductor cell 40, two backside power rails connected to opposite voltage sources may be formed in two backside power tracks PT1 and PT2 overlapping the two boundaries B1 and B2 in the 3^{rd} direction D3, as in the semiconductor cell 30. However, similar to the semiconductor cell 30, the one or more signal lines formed in the 1^{st} frontside signal track ST1 or the 4^{th} frontside signal track ST4 may not be connected to an FEOL structure or an MOL structure in the semiconductor cell 40.

In the above embodiments, it is understood that one or more backside signal tracks and one or more backside signal lines are formed for local interconnection. For example, the backside signal track BST and the backside signal line BM1 formed therein in the semiconductor cell 30 is for local connection between the source region (S) of the NMOS N0 and the shared drain region (D) of the NMOSs N3 and N4 in the semiconductor cell 30, without being extended outside the semiconductor cell 30 to avoid an unnecessary area penalty that may occur when a backside signal line is formed to connect the structural elements of the semiconductor cell 30 to that of another semiconductor cell.

It is also understood that the power rails providing two opposite voltages for the semiconductor cell may be formed on the two backside power tracks overlapping the two boundaries B1 and B2 so that these backside power rails can be shared by neighboring semiconductor cells and one or more backside signal track BST can be provided inside the semiconductor cell between the two boundaries B1 and B2.

It is further understood that only one or two signal lines are formed in a single frontside signal track or backside signal track in the above embodiments. However, the disclosure is not limited thereto, and more than two signal lines or no signal lim may be formed in a single frontside signal track or backside signal track to implement a logic circuit in a semiconductor cell formed of three or less frontside signal tracks and one or more backside signal track.

In the above embodiments, each of the transistor structures respectively formed at the 1^{st} level and the 2^{nd} level of the 3D-stacked semiconductor device based on the semiconductor cells 10-40 is described as a nanosheet transistor as shown in FIGS. 1C and 3B. However, the disclosure is not limited thereto. According to one or more other embodiments, each of these transistor structures may be a different type from the nanosheet transistor, such as FinFET, forksheet transistor, not being limited thereto.

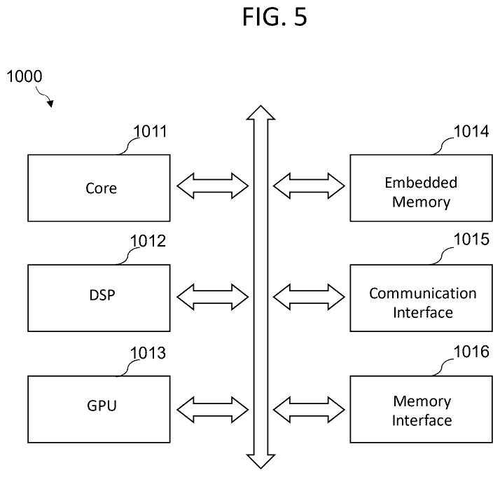

FIG. 5 is a schematic block diagram illustrating an electronic device including at least one semiconductor device formed based on at least one of the semiconductor cells 10-40 shown in FIGS. 1A-1C to 4, respectively, according to one or more embodiments.

Referring to FIG. 5, a system-on-chip (SoC) 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (RAM) (DRAM), a flash memory, etc.

At least one of the core 1011, the DSP 1012, the GPU 1013, and/or the embedded memory 1014 may include at least one of the semiconductor devices described above.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

What is claimed is:

1. A cell architecture comprising:
at most three frontside signal tracks provided at a same level on a front side of a semiconductor cell and extended in a 1^{st} direction in parallel with a 1^{st} boundary or a 2^{nd} boundary of the semiconductor cell, the 1^{st} boundary facing the 2^{nd} boundary in a 2^{nd} direction intersecting the 1^{st} direction;
at least one backside signal track provided on a back side of the semiconductor cell and extended in the 1^{st} direction; and
at least one signal line provided in at least one of the at most three frontside signal tracks and the at least one backside signal track and connected to at least one front-end-of-line (FEOL) structure or at least one middle-of-line (MOL) structure in the semiconductor cell,
wherein the at most three frontside signal tracks are arranged in the 2^{nd} direction with a predetermined pitch, and
wherein a sum number of the at most three frontside signal tracks and the at least one backside signal track is four.

2. The cell architecture of claim 1, wherein a number of the at most three frontside signal tracks is three and a number of the at least one backside signal track is one.

3. The cell architecture of claim 1, wherein the at most three frontside signal tracks and the at least one backside signal track are provided inside the semiconductor cell between the 1^{st} boundary and the 2^{nd} boundary.

4. The cell architecture of claim 1, further comprising:
a 1^{st} boundary signal track on the front side at the 1^{st} boundary;
a 2^{nd} boundary signal track on the front side at the 2^{nd} boundary; and
at least one signal line provided in at least one of the 1^{st} boundary signal track and the 2^{nd} boundary signal track.

5. The cell architecture of claim 1, wherein the semiconductor cell implements a semiconductor device configured to perform a logic function or operation within the semiconductor cell, and
wherein the at least one signal line provided in at least one of the at most three frontside signal tracks comprises a plurality of signal lines through which an input signal and an output signal of the semiconductor device are input and output, respectively.

6. The cell architecture of claim 1, further comprising:
a 1^{st} backside power track on the back side at the 1^{st} boundary;
a 2^{nd} backside power track on the back side at the 2^{nd} boundary; and
at least one power rail provided in at least one of the 1^{st} backside power track and the 2^{nd} backside power track and connected to a power source.

7. The cell architecture of claim 1, wherein the at least one FEOL structure and the at least one MOL structure form a stacked transistor structure which comprises a 1^{st} transistor at a 1^{st} level and a 2^{nd} transistor at a 2^{nd} level above the 1^{st} level in a 3^{rd} direction intersecting the 1^{st} direction and the 2^{nd} direction.

8. The cell architecture of claim 1, wherein no signal line in the at least one backside signal track connects the at least one FEOL structure or the at least one MOL structure to an outside of the semiconductor cell.

9. The cell architecture of claim 1, wherein the at least one FEOL structure comprises a plurality of FEOL structures forming at least one transistor in the semiconductor cell configured to perform a logic function,
wherein the at least one signal line comprises a plurality of signal lines at a same level in a 3^{rd} direction intersecting the 1^{st} direction and the 2^{nd} direction, and
wherein no signal line above or below the plurality of signal lines is used to connect the FEOL structures to perform the logic function.

10. The cell architecture of claim 1, wherein the at most three frontside signal tracks are the lowest signal tracks above the FEOL structure in a 3^{rd} direction intersecting the 1^{st} direction and the 2^{nd} direction.

11. The cell architecture of claim 1, wherein a number of the at most three frontside signal tracks is two and a number of the at least one backside signal track is two.

12. The cell architecture of claim 11, further comprising:
a 1^{st} backside power track on the back side at the 1^{st} boundary;
a 2^{nd} backside power track on the back side at the 2^{nd} boundary; and
at least one power rail provided in at least one of the 1^{st} backside power track and the 2^{nd} backside power track and connected to a power source.

13. The cell architecture of claim 11, wherein no signal line in the at least one backside signal track connects the at least one FEOL structure or the at least one MOL structure to an outside of the semiconductor cell.

14. A cell architecture comprising:
1^{st} to 5^{th} frontside signal tracks extended in a 1^{st} direction and arranged in a 2^{nd} direction intersecting the 1^{st} direction on a front side of a semiconductor cell, and
at least one signal line provided in at least one of the 2^{nd} to 4^{th} frontside signal tracks and connected to at least one front-end-of-line (FEOL) structure or at least one middle-of-line (MOL) structure in the semiconductor cell,
wherein at least the 2^{nd} to 4^{th} frontside signal tracks are disposed at a same level in a 3^{rd} direction intersecting the 1^{st} direction and the 2^{nd} direction,
wherein no other frontside signal track is disposed between the 1^{st} to 5^{th} frontside signal tracks, and
wherein the 1^{st} frontside signal track overlaps a 1^{st} boundary of the semiconductor cell in a 3^{rd} direction intersecting the 1^{st} direction and the 2^{nd} direction, and the 5^{th} frontside signal track overlaps a 2^{nd} boundary of the semiconductor cell in the 3^{rd} direction, the 2^{nd} boundary facing the 1^{st} boundary in the 2^{nd} direction.

15. The cell architecture of claim 14, further comprising:
a backside signal track on a back side of the semiconductor cell, and
a signal line in the backside signal track.

16. The cell architecture of claim 15, further comprising:
a 1^{st} backside power track on the back side at the 1^{st} boundary;
a 2^{nd} backside power track on the back side at the 2^{nd} boundary; and
at least one power rail provided in at least one of the 1^{st} backside power track and the 2^{nd} backside power track and connected to a power source.

17. The cell architecture of claim 15, wherein no signal line in the at least one backside signal track connects the at least one FEOL structure or the at least one MOL structure to an outside of the semiconductor cell.

18. A cell architecture comprising
a plurality of transistors configured to perform a logic function within a semiconductor cell;
three or less frontside signal tracks with a plurality of signal lines therein, the plurality of signal lines being connected to at least one of the plurality of transistors, wherein the frontside signal tracks are at a same level on a front side of the semiconductor cell inside a 1^{st} boundary and a 2^{nd} boundary of the semiconductor cell, and extended in a 1^{st} direction in parallel with the 1^{st} boundary or the 2^{nd} boundary, the 1^{st} boundary facing the 2^{nd} boundary in a 2^{nd} direction intersecting the st direction; and
one or more backside signal tracks with at least one backside signal line therein, the at least one signal line connecting at least two of the plurality of transistors.

19. The cell architecture of claim 18, further comprising:
a 1^{st} backside power track on the back side at the 1^{st} boundary;
a 2^{nd} backside power track on the back side at the 2^{nd} boundary; and
at least one power rail provided in at least one of the 1^{st} backside power track and the 2^{nd} backside power track and connected to a power source.

20. The cell architecture of claim 19, wherein the plurality of transistors are configured to perform the logic function using the plurality of signal lines and the at least one backside signal line without using another signal line formed above or below the level of the frontside signal tracks.
